(19) United States
(12) Patent Application Publication
(10) Pub. No.: US 2025/0003426 A1
(43) Pub. Date: Jan. 2, 2025

(54) LOW NOISE TURBINE FOR GEARED TURBOFAN ENGINE

(71) Applicants: RTX CORPORATION, Farmington, CT (US); MTU AERO ENGINES AG, Munich (DE)

(72) Inventors: Bruce L. Morin, Longmeadow, CT (US); Detlef Korte, Karlsfeld (DE)

(21) Appl. No.: 18/883,048

(22) Filed: Sep. 12, 2024

Related U.S. Application Data
(63) Continuation of application No. 18/201,875, filed on May 25, 2023, now Pat. No. 12,123,432.
Application No. 18/201,875 is a continuation of application No. 16/849,204, filed on Apr. 15, 2020, now abandoned.
Application No. 16/849,204 is a continuation of application No. 15/245,383, filed on Aug. 24, 2016, now abandoned.
Application No. 15/245,383 is a continuation of application No. 15/007,784, filed on Jan. 27, 2016, now abandoned.
Application No. 15/007,784 is a continuation of application No. 14/996,544, filed on Jan. 15, 2016, now abandoned.
Application No. 14/996,544 is a continuation-in-part of application No. 14/795,931, filed on Jul. 10, 2015, now abandoned.
Application No. 14/795,931 is a continuation-in-part of application No. 14/248,386, filed on Apr. 9, 2014, now abandoned.
Application No. 14/248,386 is a continuation-in-part of application No. PCT/US2013/020724, filed on Jan. 9, 2013.
(60) Provisional application No. 61/592,643, filed on Jan. 31, 2012.
(60) Provisional application No. 61/884,660, filed on Sep. 30, 2013.

(51) Int. Cl. F04D 29/66; F01D 5/06; F01D 5/14; F01D 15/12; F01D 25/24; F02C 3/04; F02C 3/107; F02C 7/36; F02K 3/04; F02K 3/06; F04D 25/04; F04D 29/053; F04D 29/32; G06F 30/17

(52) U.S. Cl. CPC F04D 29/663; F01D 5/06; F01D 5/14; F01D 15/12; F01D 25/24; F02C 3/04; F02C 3/107; F02C 7/36; F02K 3/04; F02K 3/06; F04D 25/045; F04D 29/053; F04D 29/321; F04D 29/325; G06F 30/17; F05D 2220/323; F05D 2230/50; F05D 2260/40311; F05D 2260/96; F05D 2270/304; F05D 2270/333

(57) ABSTRACT

An aircraft system includes, among other things, an aircraft and a gas turbine engine coupled to the aircraft. The gas turbine engine includes a propulsor section including a propulsor, a compressor section, a turbine section including a first turbine and a second turbine, and a gear reduction between the propulsor and the second turbine. The second turbine includes a number of turbine blades in each of a plurality of rows of the second turbine. The second turbine blades operating at least some of the time at a rotational speed. The number of blades and the rotational speed being such that the following formula holds true for at least one of the blade rows of the second turbine: 5500 Hz≤(number of blades×speed)/60 sec≤10000 Hz. The gas turbine engine is rated to produce 15,000 pounds of thrust or more. A method of operating an aircraft system is also disclosed.

### CROSS-REFERENCE TO RELATED APPLICATION

This application is a continuation of U.S. patent application Ser. No. 18/201,875, filed May 25, 2023, which is a continuation of U.S. patent application Ser. No. 16/849,204, filed Apr. 15, 2020, which is a continuation of U.S. patent application Ser. No. 15/245,383, filed Aug. 24, 2016, which is a continuation of U.S. patent application Ser. No. 15/007,784, filed Jan. 27, 2016, which is a continuation of U.S. patent application Ser. No. 14/996,544 filed Jan. 15, 2016, which is a continuation-in-part of U.S. patent application Ser. No. 14/795,931, filed Jul. 10, 2015, which is a continuation-in-part of U.S. patent application Ser. No. 14/248,386, filed Apr. 9, 2014, which is a continuation-in-part of International Application No. PCT/US2013/020724 filed Jan. 9, 2013 which claims priority to U.S. Provisional Application No. 61/592,643, filed Jan. 31, 2012. U.S. patent application Ser. No. 14/248,386 further claims priority to U.S. Provisional Application No. 61/884,660 filed Sep. 30, 2013.

### BACKGROUND

This application relates to the design of a turbine which can be operated to produce noise to which human hearing is less sensitive.

Gas turbine engines are known, and typically include a fan delivering air into a compressor. The air is compressed in the compressor and delivered downstream into a combustor section where it was mixed with fuel and ignited. Products of this combustion pass downstream over turbine rotors, driving the turbine rotors to rotate.

Typically, there is a high pressure turbine rotor, and a low pressure turbine rotor. Each of the turbine rotors includes a number of rows of turbine blades which rotate with the rotor. Typically interspersed between the rows of turbine blades are vanes.

The low pressure turbine can be a significant noise source, as noise is produced by fluid dynamic interaction between the blade rows and the vane rows. These interactions produce tones at a blade passage frequency of each of the low pressure turbine stages, and their harmonics.

The noise can often be in a frequency range to which humans are very sensitive. To mitigate this problem, in the past, a vane-to-blade ratio of the fan drive turbine has been controlled to be above a certain number. As an example, a vane-to-blade ratio may be selected to be 1.5 or greater, to prevent a fundamental blade passage tone from propagating to the far field. This is known as acoustic “cut-off.”

However, acoustically cut-off designs may come at the expense of increased weight and reduced aerodynamic efficiency. Stated another way, if limited to a particular vane to blade ratio, the designer may be restricted from selecting such a ratio based upon other characteristics of the intended engine.

Historically, the low pressure turbine has driven both a low pressure compressor section and a fan section. More recently, a gear reduction has been provided such that the fan and low pressure compressor can be driven at different speeds.

### SUMMARY

In a featured embodiment, a method of designing a gas turbine engine comprises the steps of including a fan section with a fan, the fan including at least one fan blade. The fan section is designed to achieve a low fan pressure ratio less than about 1.45, wherein the low fan pressure ratio is measured across a fan blade alone. A turbine section has a first turbine and a second turbine. A gear reduction is included between the fan and the first turbine, and includes an epicycle gear train having a gear reduction ratio of greater than about 2.5:1. The gear reduction is configured to receive an input from the first turbine and to turn the fan at a lower speed than the first turbine in operation. The first turbine is designed to achieve a pressure ratio greater than about 5:1. The first turbine includes an inlet having an inlet pressure, and an outlet that is prior to any exhaust nozzle and having an outlet pressure. The pressure ratio of the first turbine is a ratio of the inlet pressure to the outlet pressure. The first turbine is designed to further include a number of turbine blades in each of a plurality of rows of the first turbine, the first turbine blades operating at least some of the time at a rotational speed, and the number of blades and the rotational speed being such that the following formula holds true for at least one of the blade rows of the first turbine: (number of blades×speed)/60≥5500. The rotational speed is an approach speed in revolutions per minute, taken at an approach certification point as defined in Part 36 of the Federal Airworthiness Regulations. The gas turbine engine is designed to produce 15,000 pounds of thrust or more.

In another embodiment according to the previous embodiment, the formula results in a number greater than 6000.

In another embodiment according to any of the previous embodiments, the formula results in a number less than or equal to about 10000.

In another embodiment according to any of the previous embodiments, the formula results in a number less than 7000.

In another embodiment according to any of the previous embodiments, the formula holds true for a majority of the blade rows of the first turbine.

In another embodiment according to any of the previous embodiments, the formula results in a number greater than 6000.

In another embodiment according to any of the previous embodiments, the formula results in a number less than or equal to about 10000.

In another embodiment according to any of the previous embodiments, the formula results in a number less than 7000.

In another embodiment according to any of the previous embodiments, a mid-turbine frame is arranged between the second turbine and the first turbine.

In another embodiment according to any of the previous embodiments, a compressor section is configured to drive air along core flowpath, and a plurality of bearing systems is configured to support the first turbine and the second turbine. The mid-turbine frame includes airfoils positioned in the core flowpath and is configured to support at least one of the bearing systems.

In another embodiment according to any of the previous embodiments, the second turbine has two stages.

In another embodiment according to any of the previous embodiments, a first compressor is included, and a shaft is configured to be driven by the first turbine. The gear reduction is arranged intermediate the first compressor and the shaft.

In another embodiment according to any of the previous embodiments, the second turbine has two stages.

In another embodiment according to any of the previous embodiments, the engine is designed to achieve a bypass ratio greater than ten (10). The fan is designed to have a low corrected fan tip speed less than about 1150 ft/second, wherein the low corrected fan tip speed is an actual fan tip speed in ft/second at an ambient temperature divided by [(Tambient °R)/(518.7°R)]^{0.5}.

In another embodiment according to any of the previous embodiments, the fan section is designed for cruise.

In another embodiment according to any of the previous embodiments, the formula holds true for all of the blade rows of the first turbine.

In another embodiment according to any of the previous embodiments, the formula results in a number greater than 6000.

In another embodiment according to any of the previous embodiments, the formula results in a number less than or equal to about 10000.

In another embodiment according to any of the previous embodiments, the formula results in a number less than 7000.

In another embodiment according to any of the previous embodiments, the formula does not hold true for all of the blade rows of the first turbine.

In another featured embodiment, a method of designing a gas turbine engine comprises the steps of including a fan section with a fan, the fan having at least one fan blade. The fan section is designed to achieve a low fan pressure ratio less than about 1.45, wherein the low fan pressure ratio is measured across a fan blade alone. A turbine section has a first turbine and a second turbine. A gear reduction is between the fan and the first turbine and includes an epicycle gear train having a gear reduction ratio of greater than about 2.5:1. The gear reduction is configured to receive an input from the first turbine and to turn the fan at a lower speed than the first turbine in operation. The first turbine is designed to achieve a pressure ratio greater than about 5:1, the first turbine including an inlet having an inlet pressure, and an outlet that is prior to any exhaust nozzle and having an outlet pressure. The pressure ratio of the first turbine is a ratio of the inlet pressure to the outlet pressure. The first turbine is designed to further include a number of turbine blades in each of a plurality of rows of the first turbine, and the turbine blades of the first turbine operating at least some of the time at a rotational speed, and the number of blades and the rotational speed being such that the following formula holds true for at least one of the blade rows of the first turbine: (number of blades×speed)/60≥5500. The gas turbine engine is designed to produce 15,000 pounds of thrust or more.

In another embodiment according to the previous embodiment, the formula results in a number less than 7000.

In another embodiment according to any of the previous embodiments, the formula holds true for a majority of the blade rows of the first turbine.

In another embodiment according to any of the previous embodiments, the formula results in a number less than 7000.

In another embodiment according to any of the previous embodiments, a mid-turbine frame is arranged between the second turbine and the first turbine.

In another embodiment according to any of the previous embodiments, a compressor section is configured to drive air along core flowpath, and a plurality of bearing systems is configured to support the first turbine and the second turbine, wherein the mid-turbine frame includes airfoils positioned in the core flowpath and is configured to support at least one of the bearing systems.

In another embodiment according to any of the previous embodiments, a first compressor is included, and a shaft is configured to be driven by the first turbine. The gear reduction is arranged intermediate the first compressor and the shaft.

In another embodiment according to any of the previous embodiments, the engine is designed to achieve a bypass ratio greater than ten (10), wherein the fan section is designed for cruise, and wherein the fan is designed to achieve a low corrected fan tip speed less than about 1150 ft/second, wherein the low corrected fan tip speed is an actual fan tip speed in ft/second at an ambient temperature divided by [(Tambient °R)/(518.7°R)]^{0.5}.

In another embodiment according to any of the previous embodiments, the formula holds true for all of the blade rows of the first turbine.

In another featured embodiment, a method of designing a turbine section comprises the steps of including a low pressure turbine designed to achieve a pressure ratio greater than about 5:1. The low pressure turbine includes an inlet having an inlet pressure, and an outlet that is prior to any exhaust nozzle and having an outlet pressure. The pressure ratio of the low pressure turbine is a ratio of the inlet pressure to the outlet pressure. The low pressure turbine is further designed to include a number of turbine blades in each of a plurality of rows of the low pressure turbine, a majority of the turbine blades of the low pressure turbine operating at least some of the time at a rotational speed, and the number of blades and the rotational speed being such that the following formula holds true for at least one of the blade rows of the low pressure turbine: (number of blades×speed)/60≥5500. The rotational speed is an approach speed in revolutions per minute, taken at an approach certification point as defined in Part 36 of the Federal Airworthiness Regulations.

Although the different examples have the specific components shown in the illustrations, embodiments of this disclosure are not limited to those particular combinations. It is possible to use some of the components or features from one of the examples in combination with features or components from another one of the examples.

These and other features disclosed herein can be best understood from the following specification and drawings, the following of which is a brief description.

### BRIEF DESCRIPTION OF THE DRAWINGS

FIG. 1 shows a gas turbine engine.

FIG. 2 shows another embodiment.

FIG. 3 shows yet another embodiment.

### DETAILED DESCRIPTION

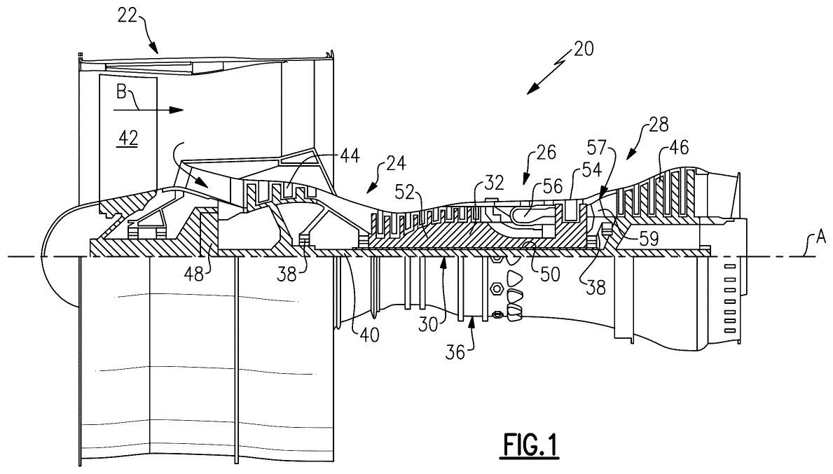

FIG. 1 schematically illustrates a gas turbine engine 20. The gas turbine engine 20 is disclosed herein as a two-spool turbofan that generally incorporates a fan section 22, a compressor section 24, a combustor section 26 and a turbine section 28. Alternative engines might include an augmentor section (not shown), or an intermediate spool, among other systems or features. The fan section 22 drives air along a bypass flowpath B while the compressor section 24 drives air along a core flowpath C for compression and communication into the combustor section 26 then expansion through the turbine section 28. Although depicted as a two-spool turbofan gas turbine engine in the disclosed non-limiting embodiment, it should be understood that the concepts described herein are not limited to use with two-spool turbofans as the teachings may be applied to other types of turbine engines including three-spool architectures.

The engine 20 generally includes a low speed spool 30 and a high speed spool 32 mounted for rotation about an engine central longitudinal axis A relative to an engine static structure 36 via several bearing systems 38. It should be understood that various bearing systems 38 at various locations may alternatively or additionally be provided.

The low speed spool 30 generally includes an inner shaft 40 that interconnects a fan 42, a low pressure compressor 44 and a low pressure turbine 46. The inner shaft 40 is connected to the fan 42 through a geared architecture 48 to drive the fan 42 at a lower speed than the low speed spool 30. The high speed spool 32 includes an outer shaft 50 that interconnects a high pressure compressor 52 and high pressure turbine 54. A combustor 56 is arranged between the high pressure compressor 52 and the high pressure turbine 54. A mid-turbine frame 57 of the engine static structure 36 is arranged generally between the high pressure turbine 54 and the low pressure turbine 46. The mid-turbine frame 57 further supports bearing systems 38 in the turbine section 28. The inner shaft 40 and the outer shaft 50 are concentric and rotate via bearing systems 38 about the engine central longitudinal axis A which is collinear with their longitudinal axes.

The core airflow is compressed by the low pressure compressor 44 then the high pressure compressor 52, mixed and burned with fuel in the combustor 56, then expanded over the high pressure turbine 54 and low pressure turbine 46. The mid-turbine frame 57 includes airfoils 59 which are in the core airflow path. The turbines 46, 54 rotationally drive the respective low speed spool 30 and high speed spool 32 in response to the expansion.

The terms “low” and “high” as applied to speed or pressure for the spools, compressors and turbines are of course relative to each other. That is, the low speed spool operates at a lower speed than the high speed spool, and the low pressure sections operate at lower pressure than the high pressures sections.

The engine 20 in one example is a high-bypass geared aircraft engine. In a further example, the engine 20 bypass ratio is greater than about six (6), with an example embodiment being greater than ten (10), the geared architecture 48 is an epicyclic gear train, such as a star system, a planetary gear system or other gear system, with a gear reduction ratio of greater than about 2.3:1 or greater than about 2.5:1. In one disclosed embodiment, the engine 20 bypass ratio is greater than about ten (10:1), the fan diameter is significantly larger than that of the low pressure compressor 44, and the low pressure turbine 46 has a pressure ratio that is greater than about 5:1. The low pressure turbine 46 pressure ratio is a ratio of the pressure measured at inlet of low pressure turbine 46 to the pressure at the outlet of the low pressure turbine 46 (prior to an exhaust nozzle). It should be understood, however, that the above parameters are only exemplary of one embodiment of a geared architecture engine and that the present invention is applicable to other gas turbine engines including direct drive turbofans.

A significant amount of thrust is provided by the bypass flow B due to the high bypass ratio. The fan section 22 of the engine 20 is designed for a particular flight condition—typically cruise at about 0.8 Mach and about 35,000 feet. The flight condition of 0.8 Mach and 35,000 ft, with the engine at its best fuel consumption—also known as “bucket cruise Thrust Specific Fuel Consumption (‘TSFC’)”—is the industry standard parameter of lbm of fuel being burned divided by lbf of thrust the engine produces at that minimum point. “Low fan pressure ratio” is the pressure ratio across the fan blade alone, without a Fan Exit Guide Vane (“FEGV”) system. The low fan pressure ratio as disclosed herein according to one non-limiting embodiment is less than about 1.50 and, in some embodiments, is less than about 1.45. “Low corrected fan tip speed” is the actual fan tip speed in ft/sec divided by an industry standard temperature correction of [(Tambient deg R)/518.7)\hat{ }0.5]. The “Low corrected fan tip speed” as disclosed herein according to one non-limiting embodiment is less than about 1150 ft/second.

The use of the gear reduction between the low pressure turbine spool and the fan allows an increase of speed to the low pressure compressor. In the past, the speed of the low pressure turbine has been somewhat limited in that the fan speed cannot be unduly high. The maximum fan speed is at its outer tip, and in larger engines, the fan diameter is much larger than it may be in lower power engines. However, a gear reduction may be used to free the designer from compromising low pressure turbine speed in order not to have unduly high fan speeds.

It has been discovered that a careful design between the number of rotating blades, and the rotational speed of the low pressure turbine can be selected to result in noise frequencies that are less sensitive to human hearing.

A formula has been developed as follows:

(blade count×rotational speed)/(60 seconds/minute)≥4000 Hz.

That is, the number of rotating blades in any low pressure turbine stage, multiplied by the rotational speed of the low pressure turbine (in revolutions per minute), divided by 60 seconds per minute (to put the amount per second, or Hertz) should be greater than or equal to 4000 Hz. In one embodiment, the amount is above 5500 Hz. And, in another embodiment, the amount is above about 6000 Hz.

The operational speed of the low pressure turbine as utilized in the formula should correspond to the engine operating conditions at each noise certification point currently defined in Part 36 or the Federal Airworthiness Regulations. More particularly, the rotational speed may be taken as an approach certification point as currently defined in Part 36 of the Federal Airworthiness Regulations. For purposes of this application and its claims, the term “approach speed” equates to this certification point.

Although the above formula only needs to apply to one row of blades in the low pressure turbine 26, in one embodiment, all of the rows in the low pressure turbine meet the above formula. In another embodiment, the majority of the blade rows in the low pressure turbine meet the above formula.

This will result in operational noise to which human hearing will be less sensitive.

In embodiments, it may be that the formula can result in a range of greater than or equal to 4000 Hz, and moving higher. Thus, by carefully designing the number of blades and controlling the operational speed of the low pressure turbine (and a worker of ordinary skill in the art would recognize how to control this speed) one can assure that the noise frequencies produced by the low pressure turbine are of less concern to humans.

This invention is most applicable to jet engines rated to produce 15,000 pounds of thrust or more and with bypass ratios greater than about 8.0.

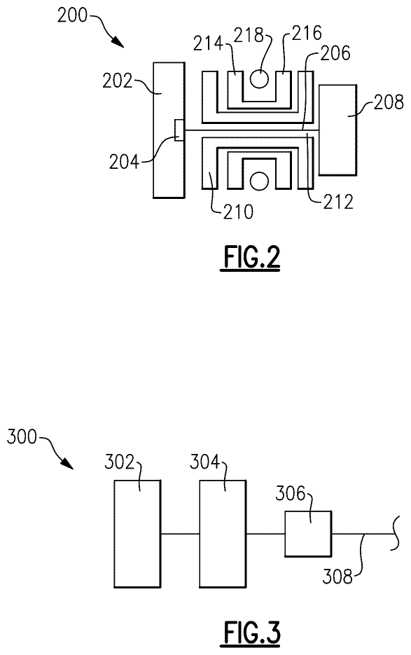

FIG. 2 shows an embodiment 200, wherein there is a fan drive turbine 208 driving a shaft 206 to in turn drive a fan rotor 202. A gear reduction 204 may be positioned between the fan drive turbine 208 and the fan rotor 202. This gear reduction 204 may be structured and operate like the gear reduction disclosed above. A compressor rotor 210 is driven by an intermediate pressure turbine 212, and a second stage compressor rotor 214 is driven by a turbine rotor 216. A combustion section 218 is positioned intermediate the compressor rotor 214 and the turbine section 216.

FIG. 3 shows yet another embodiment 300 wherein a fan rotor 302 and a first stage compressor 304 rotate at a common speed. The gear reduction 306 (which may be structured as disclosed above) is intermediate the compressor rotor 304 and a shaft 308 which is driven by a low pressure turbine section.

Although an embodiment of this invention has been disclosed, a worker of ordinary skill in this art would recognize that certain modifications would come within the scope of this invention. For that reason, the following claims should be studied to determine the true scope and content of this invention.

What is claimed is:

1. An aircraft system comprising:
an aircraft; and
a gas turbine engine coupled to the aircraft, wherein the gas turbine engine comprises:
a propulsor section including a propulsor;
a compressor section that drives air from the propulsor along a core flowpath, the compressor section including a first compressor and a second compressor, the first compressor including a plurality of stages, and the second compressor including a plurality of stages;
a turbine section including a first turbine and a second turbine, wherein the first turbine drives the second compressor, and the second turbine includes a greater number of stages than the first turbine;
a gear reduction between the propulsor and the second turbine, the gear reduction including an epicycle gear train having a gear reduction ratio of greater than 2.5:1, and the gear reduction receiving an input from the second turbine such that the propulsor turns at a lower speed than the second turbine;
wherein the second turbine includes a number of turbine blades in each of a plurality of rows of the second turbine, the second turbine blades operating at least some of the time at a rotational speed, and the number of turbine blades and the rotational speed being such that the following formula holds true for at least one row of the plurality of rows of the second turbine: 5500 Hz≤(number of blades×speed)/60 sec≤10000 Hz;
wherein the rotational speed is an approach speed in revolutions per minute taken at an approach certification point as defined in Part 36 of the Federal Airworthiness Regulations; and
wherein the gas turbine engine is rated to produce 15,000 pounds of thrust or more.

2. The aircraft system as recited in claim 1, wherein more than one row of the plurality of rows meet the formula.

3. The aircraft system as recited in claim 2, wherein the formula results in a number greater than 6000 Hz for at least one row of the plurality of rows of the second turbine.

4. The aircraft system as recited in claim 2, wherein the formula results in a number less than 7000 Hz for at least one row of the plurality of rows of the second turbine.

5. The aircraft system as recited in claim 2, wherein the epicycle gear train is a star gear system.

6. The aircraft system as recited in claim 2, wherein the epicycle gear train is a planetary gear system.

7. The aircraft system as recited in claim 6, wherein a majority of the plurality of rows meet the formula.

8. The aircraft system as recited in claim 7, wherein the first compressor includes three stages.

9. The aircraft system as recited in claim 8, wherein the second turbine drives the first compressor and an input of the gear reduction.

10. The aircraft system as recited in claim 8, wherein the formula holds true for all of the plurality of rows of the second turbine.

11. The aircraft system as recited in claim 8, wherein:
the formula results in a number less than 7000 Hz for the majority of the plurality of rows of the second turbine.

12. The aircraft system as recited in claim 6, wherein:
the first turbine includes two stages; and
the first compressor includes three stages.

13. The aircraft system as recited in claim 6, wherein the propulsor is a fan including at least one fan blade, and an outer housing surrounds the fan to define a bypass duct, and further comprising:
a bypass ratio of greater than 10, and a low fan pressure ratio less than 1.45 at cruise at 0.8 Mach and 35000 feet, the low fan pressure ratio measured across the at least one fan blade alone.

14. The aircraft system as recited in claim 13, wherein the epicycle gear train is a planetary gear system.

15. The aircraft system as recited in claim 14, wherein the formula results in a number greater than 6000 Hz for at least one row of the plurality of rows of the second turbine.

16. The aircraft system as recited in claim 14, wherein the formula results in a number less than 7000 Hz for at least one row of the plurality of rows of the second turbine.

17. The aircraft system as recited in claim 16, wherein the formula results in a number equal to or greater than 5500 Hz, and less than or equal to 10000 Hz, for a majority of the plurality of rows of the second turbine.

18. The aircraft system as recited in claim 17, wherein the second turbine drives the first compressor and an input of the gear reduction.

19. The aircraft system as recited in claim 18, wherein:
the gas turbine engine is a two-spool engine including a low speed spool and a high speed spool;
the low speed spool includes a first shaft that interconnects the fan, the first compressor and the second turbine; and
the high speed spool includes a second shaft that interconnects the second compressor and the first turbine.

20. The aircraft system as recited in claim 19, further comprising:
a mid-turbine frame arranged between the first turbine and the second turbine;
a plurality of bearing systems that support the first turbine and the second turbine; and
wherein the mid-turbine frame includes airfoils positioned in the core flowpath and supports at least one of the bearing systems.

21. A method of operating an aircraft system including an aircraft and a gas turbine engine coupled to the aircraft, the gas turbine engine including a propulsor section including a propulsor, a gear reduction, a compressor section that drives air from the propulsor along a core flowpath, the compressor section including a first compressor and a second compressor, and a turbine section including a first turbine and a second turbine, the method comprising:
driving the propulsor;
driving the first compressor;
driving the second compressor by the first turbine, wherein the first compressor includes a plurality of stages, the second compressor includes a plurality of stages, and the second turbine includes a greater number of stages than the first turbine;
driving an input to the gear reduction between the propulsor and the second turbine, the gear reduction including an epicycle gear train having a gear reduction ratio of greater than 2.5:1, and the gear reduction receiving an input from the second turbine such that the propulsor turns at a lower speed than the second turbine;
wherein the second turbine includes a number of turbine blades in each of a plurality of rows of the second turbine; and
wherein the step of driving the input to the gear reduction includes operating the second turbine blades at least some of the time at a rotational speed, the number of turbine blades and the rotational speed being such that the following formula holds true for at least one row of the plurality of rows of the second turbine: 5500 Hz≤(number of blades×speed)/60 sec≤10000 Hz, wherein the rotational speed is an approach speed in revolutions per minute taken at an approach certification point of the aircraft as defined in Part 36 of the Federal Airworthiness Regulations, and wherein the gas turbine engine is rated to produce 15,000 pounds of thrust or more.

22. The method as recited in claim 21, wherein the step of operating the second turbine blades at the rotational speed occurs such that more than one row of the plurality of rows meet the formula.

23. The method as recited in claim 22, wherein the step of operating the second turbine blades at the rotational speed occurs such that the formula results in a number greater than 6000 Hz for at least one row of the plurality of rows of the second turbine.

24. The method as recited in claim 22, wherein the step of operating the second turbine blades at the rotational speed occurs such that the formula results in a number less than 7000 Hz for at least one row of the plurality of rows of the second turbine.

25. The method as recited in claim 22, wherein the epicycle gear train is a planetary gear system.

26. The method as recited in claim 25, wherein the step of operating the second turbine blades at the rotational speed occurs such that the formula holds true for a majority of the plurality of rows of the second turbine.

27. The method as recited in claim 26, wherein the step of operating the second turbine blades at the rotational speed occurs such that the formula results in a number less than 7000 Hz for the majority of the plurality of rows of the second turbine.

28. The method as recited in claim 26, wherein the propulsor is a fan including at least one fan blade, an outer housing surrounds the fan to define a bypass duct, and the step of driving the propulsor occurs such that the fan delivers a portion of airflow to the bypass duct and another portion of airflow to the compressor section to achieve a bypass ratio of greater than 10.

29. The method as recited in claim 28, wherein:
the step of operating the second turbine blades at the rotational speed occurs such that the formula results in a number greater than 6000 Hz for the majority of the plurality of rows of the second turbine; and/or
the step of operating the second turbine blades at the rotational speed occurs such that the formula results in a number less than 7000 Hz for the majority of the plurality of rows of the second turbine.

30. The method as recited in claim 28, wherein:
the gas turbine engine is a two-spool engine including a low speed spool and a high speed spool;
the low speed spool includes a first shaft that interconnects the fan, the first compressor and the second turbine; and
the high speed spool includes a second shaft that interconnects the second compressor and the first turbine.
